(19) United States
(12) Patent Application Publication
(10) Pub. No.: US 2019/0135999 A1
(43) Pub. Date: May 9, 2019

(54) HYDROLYSIS STABLE COMPOSITIONS FOR FILMS IN SOLAR CELLS

(71) Applicant: LANXESS Deutschland GmbH, Cologne (DE)

(72) Inventor: Wilhelm LAUFER, Ellerstadt (DE)

(73) Assignee: LANXESS Deutschland GmbH, Cologne (DE)

(21) Appl. No.: 16/310,913

(22) PCT Filed: May 30, 2017
(86) PCT No.: PCT/EP2017/062947

§ 371 Date: Dec. 18, 2018

(30) Foreign Application Priority Data
Jun. 22, 2016 (EP) 16175623.4

(51) Int. Cl. C08J 5/18; C08L 79/08; C08L 67/02; C08L 67/04; C08K 5/29

(52) U.S. Cl. CPC C08J 5/18; C08L 79/08; C08L 67/02; C08L 2203/204; C08K 5/29; C08J 2367/02; C08J 2479/08; C08L 67/04

(57) ABSTRACT

The present invention relates to novel compositions stable to hydrolysis, especially for films in solar cells, which are characterized by improved resistance to hydrolysis, and also to the solar cells comprising these films.

The present invention relates to novel compositions stable to hydrolysis, especially for films in solar cells, which are characterized by improved resistance to hydrolysis, and also to the solar cells comprising these films.

The generation of electricity by photovoltaics has experienced an upturn due to the withdrawal from nuclear energy adopted across Germany.

In photovoltaic generation of electricity, as is known, energy from the sun is converted directly to electrical energy by a silicon cell semiconductor. This solar cell element, however, experiences a reduction in quality if it is brought into direct contact with ambient air. This is why a solar cell element is generally arranged between a sealing material and a transparent surface protective material (usually glass) and a surface protective material on the reverse side (a backing film on the reverse side composed of, for example, a polyester resin, a fluororesin or the like), in order to achieve a buffer effect and to prevent penetration by foreign bodies and especially of moisture.

Fluororesins (plastics based on polyvinyl fluoride) are suitable particularly for this application sector due to their inertness, but these are so expensive to produce and are frequently unavailable in sufficient quantity such that they are avoided in favour of polyester resins that are unstable to hydrolysis. Development work is therefore primarily directed at hydrolysis resistance of the polyester resin layer.

For this purpose, for example, polymeric carbodiimides are used having number-average molar masses of 2000-100,000, see EP-A 2262000. In this case, aliphatic carbodiimides such as, for example, Carbodilite® LA-1 or Carbodilite® HMV-8CV, are especially preferred. However, these have the disadvantage that they are inadequate as hydrolysis inhibitors or are only effective at high concentrations. Aromatic polycarbodiimides with very high molecular masses exhibit good hydrolysis resistance in PET (see EP-A-2748234) but insufficient in biobased plastics such as polylactides (PLA) and are very expensive to procure due to the complex production. Moreover, their use results in an unsatisfactory emission of isocyanates which renders an industrial scale production of films quite impossible.

The object of the present invention therefore consisted of providing compositions for films for solar cells based on polyesters which do not possess the disadvantages of the prior art and are above all cost-efficient and stable to hydrolysis.

It has now been found that, surprisingly, a composition comprising at least one polyester and at least one polymeric carbodiimide according to formula (I)

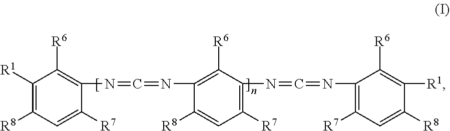

where R¹ may be identical or different and is selected from the group comprising NHCONHR³, —NHCONR³R⁴ or —NHCOOR⁵,

where R³ and R⁴ are identical or different and represent a C₁-C₁₂-alkyl, C₆-C₁₂-cycloalkyl, C₇-C₁₅-aralkyl radical or aryl radical,

R⁵ represents a C₁-C₂₂-alkyl, C₆-C₁₂-cycloalkyl, C₆-C₁₅-aryl or C₇-C₁₅-aralkyl radical, and an unsaturated alkyl radical having 2-22 carbon atoms, preferably 12-20, particularly preferably 16-18 carbon atoms, or an alkoxypolyoxy-C₁-C₁₂-alkylene radical,

R⁶, R⁷ and R⁸ are each independently methyl or ethyl, but only a maximum of one of the radicals R⁶, R⁷ and R⁸ is methyl and n denotes 1 to 5, having a number-average molar mass Mₙ of >1000 to <2000 g/mol, determined by GPC, measured in tetrahydrofuran (THF) against polystyrene as standard.

The present invention therefore relates to compositions comprising at least one polyester and at least one polymeric carbodiimide according to formula (I)

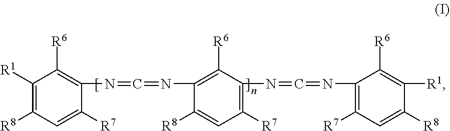

where R¹ may be identical or different and is selected from the group comprising NHCONHR³, —NHCONR³R⁴ or —NHCOOR⁵,

wherein R³ and R⁴ are identical or different and represent a C₁-C₁₂-alkyl, C₆-C₁₂-cycloalkyl, C₇-C₁₅-aralkyl radical or aryl radical,

R⁵ represents a C₁-C₂₂-alkyl, C₆-C₁₂-cycloalkyl, C₆-C₁₅-aryl or C₇-C₁₅-aralkyl radical, and an unsaturated alkyl radical having 2-22 carbon atoms, preferably 12-20, particularly preferably 16-18 carbon atoms, or an alkoxypolyoxy-C₁-C₁₂-alkylene radical,

R⁶, R⁷ and R⁸ are each independently methyl or ethyl, but only a maximum of one of the radicals R⁶, R⁷ and R⁸ is methyl and n denotes 1 to 5, having a number-average molar mass Mₙ of >1000 to <2000 g/mol, determined by GPC, measured in tetrahydrofuran (THF) against polystyrene as standard.

The measurements of the number-average molar mass were evaluated using a combination of RI detector (refractive index) and viscosity detector (universal calibration).

In a particularly preferred embodiment of the invention are the polymeric aromatic carbodiimide of the formula (I) where n=3 and R¹=—NHCOOR⁵ where R⁵=cyclohexyl, and where R⁶, R⁷ and R⁸ are methyl or ethyl, with the proviso that a maximum of only one of the radicals R⁶, R⁷ and R⁸ is methyl. It is furthermore preferred that n=3 is an arithmetic mean value of the measurements.

In one embodiment of the invention, the numerical values specified for n in formula (I) are arithmetic mean values.

The number-average molar masses were determined by GPC (gel permeation chromatography), measured in tetrahydrofuran (THF) against polystyrene as standard. This was evaluated using a combination of RI detector (refractive index) and viscosity detector (universal calibration). The calibration with polystyrene was carried out using reference polystyrenes of different molar masses from PSS Polymer Standards Service GmbH.

In the context of the invention, the polymeric carbodiimides are preferably aromatic polymeric carbodiimides of the formula (I) having a number-average molar mass Mₙ of >1000 to <2000 g/mol. These are commodity chemicals and are available, for example from Rhein Chemie Rheinau GmbH.

The carbodiimide content (NCN content measured by titration with oxalic acid) of the carbodiimides used according to the invention is preferably 2-12% by weight, preferably 4-8% by weight, particularly preferably 5-7% by weight.

In one embodiment of the present invention, the polyester is polyethylene terephthalate (PET), polyethylene naphthalate (PEN), polybutylene terephthalate (PBT), polytrimethylene terephthalate (PTT) and/or polycyclohexanedimethanol terephthalate (PCT), ester-based thermoplastic elastomers such as TPE-U or TPE-E and also biobased and/or biodegradable or compostable polyesters such as Ecoflex from BASF, polybutylene adipate therephthalate PBAT (Ecovio from BASF), polylactides (PLA, from Natureworks for example) or polyhydroxyalkoxides (PHA). In this case, particular preference is given to polyethylene terephthalate (PET), polybutylene adipate terephthalate (PBAT) and polylactide (PLA).

In a further embodiment of the invention, the polyester is a mixture of polyesters. In this connection, preference is given to a mixture of polyethylene terephthalate (PET) and polyethylene naphthalate (PEN) and also a mixture of polyethylene terephthalate (PET) and polylactide (PLA).

The polyesters are commodity substances obtainable, for example, from Invista, Novapet S. A., BASF, NatureWorks.

In a further preferred embodiment of the invention, the amount of polymeric carbodiimide of the formula (I), based on the polyester, is 0.5-2.5% by weight, preferably 1.0-2.0% by weight.

The present invention further relates to films comprising the composition according to the invention.

The films according to the invention may also comprise further additives such as, for example, pigments, dyes, fillers, stabilizers, antioxidants, plasticizers, processing aids, crosslinkers etc.

The film according to the invention is preferably produced according to the following method.

In one embodiment of the invention, the polymeric carbodiimide of the formula (I) having a number-average molar mass Mₙ of >1000 to <2000 g/mol is incorporated into the polyester at the desired concentration by means of a kneader and/or extruder.

In a further embodiment of the invention, the polymeric carbodiimide of the formula (I) is incorporated into the polyester in the form of a polyester-containing master batch by means of a kneader and/or extruder. In this case, the concentration of the carbodiimide in the master batch is preferably 10-20% by weight. The following devices may preferably be employed for the production: single-screw, twin-screw or multi-screw extruders, planetary extruders, cascade extruders, continuous co-kneaders (Buss-type) and discontinuous kneaders, e.g. Banbury-type and other units customary in the polymer industry.

Optionally used additives, pigments, dyes, fillers, stabilizers, antioxidants, plasticizers, processing aids, crosslinkers, are preferably incorporated into the polyester with the polymeric carbodiimide in a mixing step. The sequence of addition of carbodiimide and additive can be selected arbitrarily in this case.

The film is preferably produced by mixing carbodiimide or carbodiimide master batch and polyester in a melt and subsequent melt extrusion, see also EP-A 2262000.

In a preferred embodiment of the invention, the film is oriented biaxially. In one embodiment of the invention, the biaxially oriented film is produced by applying a thin layer of the molten composition according to the invention, using PET as polyester for example, on a roller, firstly in the direction of the roller and then extending it orthogonally to the direction of rotation of the roller (BOPET).

In one embodiment of the invention, the biaxially oriented film is produced on a BOPET machine, which is partly or fully sealed in order to minimize the emission of toxic gases during preparation and/or is provided with special exhaust air extraction, that are commercially available for example.

The films may be produced in any desired thickness. However, film thicknesses between 25 and 300 micrometers are preferred.

The present invention also relates to the use of the films according to the invention in solar cells, where they are preferably used for sealing and thus for protecting from environmental influences, for example moisture and ingress of foreign objects.

The present invention also relates to a solar cell module comprising at least one film according to the invention, preferably as a backing cover.

Solar cells generally consist of several layers of different materials, such as
front glass, composed of windscreens for example or transparent substrates such as polycarbonate,
silicon wafers, which are laminated in embedding films, generally consisting of ethylene vinyl acetate,
a backing film of polyvinyl fluoride and/or polyester and
an aluminium frame.

In addition, solar cells are also known in which transparent polymer layers are positioned between the front glass and the silicon wafer, for example composed of a-olefin-vinyl acetate copolymers with olefins selected from ethene, propene, butene, pentene, hexene, heptene and octene, such as described, for example, in EP-A 2031662.

In the present invention, the film according to the invention is used in solar cells as a backing film. In this case, the film can be used in all solar cells known from the prior art.

The solar cell in this case is produced according to the methods described in the prior art, starting from the standard methods for producing silicon via the casting process, Bridgeman method, EFG (edge-defined film-fed growth) process or the Czochralski process, and the subsequent production of the Si wafer and the laminating of the aforementioned material layers, wherein instead of the backing film used as standard, the film according to the invention is used. The individual layers of the solar cell can also be attached to one another in this case in laminating processes, see EP-A 2031662.

The scope of the invention encompasses all hereinabove and hereinbelow recited general or preferred definitions of radicals, indices, parameters and elucidations among themselves, i.e. including between the respective ranges and preferences in any combination.

The examples which follow serve to elucidate the invention but have no limiting effect.

### Exemplary Embodiments

In the examples, the following substances were used:

PET=polyethylene terephthalate from Invista, used in Examples 1 to 5.

PLA=polylactide (polylactic acid) from NatureWorks in Examples 6 to 16.

In Examples No. 2 and 7, the aforementioned PET or PLA was extruded once in a laboratory twin screw extruder ZSK 25 from Werner & Pfleiderer prior to the measurement described below.

CDI 1 (comparitive)=Bis-2,6-diisopropylphenylcarbodiimide, a monomeric aromatic carbodiimide having a number-average molar mass of Mn=270 g/mol, and an NCN content of ca. 11% by weight, used in Examples 3, 8 and 13.

CDI 2 (comparative)=a polymeric aromatic carbodiimide of the formula R¹⁰-R⁹-(—N═C═N—R⁹—)ₘ—R¹⁰ where R⁹=triisopropylphenylene and R¹⁰=—NCNR⁹ having a number-average molar mass of Mn=1700 g/mol, and an NCN content of ca. 13% by weight, is used in Examples 4, 9 and 14.

CDI 3 (comparative)=a polymeric aromatic carbodiimide of the formula R¹¹-R⁹-(—N═C═N—R⁹—)ₘ—R¹¹ where R⁹=triisopropylphenylene and R¹¹ =-NCO having a number-average molar mass of ca. Mn=5700 g/mol, and an NCN content of ca. 13.5% by weight, used in Examples 10 and 15.

CDI 4 (inventive)=polymeric aromatic carbodiimide of the formula (I) where n =3 as arithmetic mean value and R¹=—NHCOOR⁵ where R⁵=cyclohexyl, and R⁶, R⁷=ethyl and R⁸=methyl, having a number-average molar mass: ca. 1400 g/mol, and an NCN content of ca. 11% by weight, used in Examples 5, 11 and 16.

CDI 5 (comparative)=polymeric aromatic carbodiimide of the formula (I) where n=2-3 as arithmetic mean value and R¹=—NHCOOR⁵ where R⁵=cyclohexyl, and R⁶, R⁷=ethyl and R⁸=methyl, having a number-average molar mass: ca. 790 g/mol, and an NCN content of ca. 11% by weight, used in Examples 5, 11 and 16.

CDI 6 (comparative)=polymeric aromatic carbodiimide of the formula (I) where n=3-4 as arithmetic mean value and R¹=—NHCOOR⁵ where R⁵=cyclohexyl, and R⁶, R⁷=ethyl and R⁸=methyl, having a number-average molar mass: ca. 2180 g/mol, and an NCN content of ca. 11% by weight, used in Examples 5, 11 and 16.

The carbodiimide was incorporated into the PET and the PLA by means of a laboratory twin screw extruder ZSK 25 from Werner & Pfleiderer.

The nature and amount of the carbodiimide used are presented in Table 1, and the measurement results in relation to the stability to hydrolysis.

F3 standard test specimens used for measuring elongation at break were then created on an Arburg Allrounder 320 S 150-500 injection moulding machine.

For the hydrolysis test, these F3 standard test specimens were then stored for several days at a temperature of 110° C. in steam in the case of PET and at 65° C. in water in the case of PLA and the elongation at break thereof was measured after 0, 1, 3 and 5 days in the case of PET and 0, 1, 2, 3 and 6 days in the case of PLA.

The number-average molar masses were determined by GPC (gel permeation chromatography), measured in THF against polystyrene as standard, evaluated using a combination of RI detector (refractive index) and viscosity detector (universal calibration). For this purpose, a measuring instrument from Thermo Scientific was used. The calibration with polystyrene was carried out using reference polystyrenes of different molar masses from PSS Polymer Standards Service GmbH.

The values stated in Tables 1 and 2 for the elongation at break are derived from the following calculation:

Elongation at break [%]=(elongation at break after X days/elongation at break after 0 days) ×100

TABLE 1

| Ex. No | 1 | 2 | 3 | 4 | 5 |
|---|---|---|---|---|---|
| | C | C | C | C | I |
| Amount of CDI [%] | 0 | 0 | 1.5 | 1.5 | 1.5 |
| CDI | — | — | CDI 1 | CDI 2 | CDI 4 |
| Elongation at break | 80 | 69 | 100 | 88 | 100 |
| [%] | | | | | |
| (X = 1 day) | | | | | |
| Elongation at break | 30 | 0 | 61 | 37 | 95 |
| [%] | | | | | |
| (X = 3 days) | | | | | |
| Elongation at break | 0 | 0 | 40 | 0 | 52 |
| [%] | | | | | |
| (X = 5 days) | | | | | |

C = comparative experiment,
I = inventive

TABLE 2

| | Ex. No | | | | | |
|---|---|---|---|---|---|---|
| | 6 | 7 | 8 | 9 | 10 | 11 |
| | C | C | C | C | C | I |
| Amount of CDI [%] | 0 | 0 | 1.5 | 1.5 | 1.5 | 1.5 |
| CDI | — | — | CDI 1 | CDI 2 | CDI 3 | CDI 4 |
| Elongation at break | 64 | 55 | 100 | 100 | 100 | 100 |
| [%] (X = 1 day) | | | | | | |
| Elongation at break | 12 | 0 | 100 | 100 | 90 | 100 |
| [%] (X = 2 days) | | | | | | |
| Elongation at break | 0 | 0 | 61 | 100 | 28 | 100 |
| [%] (X = 3 days) | | | | | | |
| Elongation at break | 0 | 0 | 0 | 0 | 0 | 89 |
| [%] (X = 6 days) | | | | | | |

C = comparative experiment,
I = inventive

It is apparent that by using the carbodiimide according to the invention, despite the low number-average molar mass, the highest stability to hydrolysis can be achieved.

### Measurement of Emissions (Off-Gassing)

The exhaust air measurement for determining the isocyanate emissions was effected during the incorporation of the carbodiimide into the polylactide (PLA) by means of a laboratory twin screw extruder ZSK 25 from Werner & Pfleiderer.

For this purpose, a portion of the exhaust air flow was passed directly at the nozzle at 2 l/min for 30 min through a tube impregnated with a derivatizing agent. The amount of isocyanate was then determined by HPLC (duplicate determination).

The emission values using various carbodiimides are compiled in Table 3:

TABLE 3

| Ex. No | 12 | 13 | 14 | 15 | 16 |
|---|---|---|---|---|---|
| | C | C | C | C | I |
| Amount of CDI [%] | 0 | 1.5 | 1.5 | 1.5 | 1.5 |
| CDI | — | CDI 1 | CDI 2 | CDI 3 | CDI 4 |
| Isocyanate | — | 3440/3450 | 960/950 | 480/480 | 240/230 |
| concentration | | | | | |
| [ppm] | | | | | |

It is apparent that the polymeric carbodiimides of the composition according to the invention exhibit extremely improved emissions characteristics.

The influence of the number-average molecular weight on the processability and properties thereof in the film production is evident from Table 4 below.

TABLE 4

| CDI | Mn | Ability to pelletize | Film production |
|---|---|---|---|
| CDI 5 | 790 g/mol | not pelletable, soft, | very good homogeneous |
| (C)) | | sticky | film, transparent |
| CDI 4 | 1400 g/mol | very good, brittle | good homogeneous film, |
| | | | transparent |
| CDI 6 | 2180 g/mol | good, brittle, slight | non-homogeneous film, |
| (C)) | | threads drawn | haze formation |

Only the carbodiimide according to the invention having a number-average molecular weight between 1000 and 2000 g/mol shows a very good ability to pelletize and affords homogeneous and transparent films.

1. A composition comprising at least one polyester and at least one polymeric carbodiimide according to formula (I) 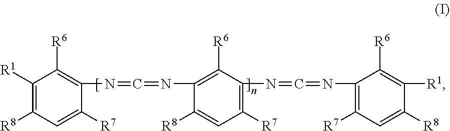
where:
R¹ may be identical or different and is selected from the group comprising NHCONHR³, —NHCONR³R⁴ or —NHCOOR⁵, wherein:
R³ and R⁴ are identical or different and represent a C₁-C₁₂-alkyl, C₆-C₁₂-cycloalkyl, C₇-C₁₈-aralkyl radical or aryl radical, and
R⁵ represents a C₁-C₂₂-alkyl, C₆-C₁₂cycloalkyl, C₆-C₁₈aryl or C₇-C₁₈aralkyl radical, and an unsaturated alkyl radical having 2-22 carbon atoms, preferably 12-20, particularly preferably 16-18 carbon atoms, or an alkoxypolyoxy-C₁-C₁₂-alkylene radical,
R⁶, R⁷ and R⁸ are each independently methyl or ethyl, but only a maximum of one of the radicals R⁶, R⁷ and R⁸ is methyl, and
n denotes 1 to 5, and
the carbodiimides have a number-average molar mass Mₙ of >1000 to <2000 g/mol, determined by GPC, measured in tetrahydrofuran (THF) against polystyrene as standard.

2. The composition according to claim 1, wherein the polyester is selected from the group consisting of polyethylene terephthalate (PET), polyethylene naphthalate (PEN), polybutylene terephthalate (PBT), polytrimethylene terephthalate (PTT), polycyclohexanedimethanol terephthalate (PCT), ester-based thermoplastic elastomers, and biobased and/or biodegradable or compostable polyesters, and mixtures thereof.

3. A film comprising the composition of claim 1.

4. The film according to claim 3, wherein the film is biaxially oriented.

5. A soar cell module comprising the film according to claim 3, preferably as backing cover.

6. A method for isolating solar cells from ambient environment, the method comprising enclosing at least a portion of the solar cells within the film according to claim 3 for sealing of the solar cell.

7. The film according to claim 3, wherein the film comprises 0.5-2.5% by weight of the at least one polymeric carbodiimide of the formula (I), based on the polyester.

8. The film according to claim 3, wherein the film comprises 1.0-2.0% by weight of the at least one polymeric carbodilmide of the formula (I), based on the polyester.

9. The composition according to claim 2, comprising 0.5-2.5% by weight, based on the polyester, of the carbodilmide.

10. The composition according to claim 1, wherein:
n=3;
R¹=—NHCOOR⁶ where R⁵=cyclohexyl, and
R⁶, R⁷ and R⁸ are methyl or ethyl, with the proviso that a maximum of only one of the radicals R⁵, R⁷ and R⁸ is methyl.

10. The composition according to claim 10, wherein the polyester is selected from the group consisting of polyethylene terephthalate (PET), polyethylene naphthalate (PEN), polybutylene terephthalate (PBT), polytrimethylene terephthalate (PTT), polycyclohexanedimethanol terephthalate (PCT), thermoplastic urethane elastomers (TPE U), thermoplastic copolyester elastomer (TPE E), polybutylene adipate therephthalate PBAT, polylactides (PLA), and polyhydroxyalkoxides (PHA), and mixtures thereof.

12. The composition according to claim 11, wherein the at least one polyester comprises a mixture of polyethylene terephthalate (PET) and polyethylene naphthalate (PEN) or a mixture of polyethylene terephthalate (PET) and polylactide (PLA).

13. The composition according to claim 12, comprising 1-2% by weight, based on the polyester, of the carbodlimide.
